(19) United States
(12) Patent Application Publication
(10) Pub. No.: US 2026/0057163 A1
(43) Pub. Date: Feb. 26, 2026

(54) METHOD FOR MODELING WAFER SHAPE, AND METHOD FOR MANUFACTURING WAFER

(71) Applicant: SUMCO CORPORATION, Tokyo (JP)

(72) Inventor: Masahiro MURAKAMI, Tokyo (JP)

(73) Assignee: SUMCO CORPORATION, Tokyo (JP)

(21) Appl. No.: 19/113,502

(22) PCT Filed: Jul. 11, 2023
(86) PCT No.: PCT/JP2023/025565

§ 371 Date: Mar. 20, 2025

(30) Foreign Application Priority Data
Sep. 21, 2022 (JP) 2022-150142

(51) Int. Cl. G06F 30/39

(52) U.S. Cl. CPC G06F 30/39

(57) ABSTRACT

A method for modeling a wafer profile by a function is provided in which the function is used for calculating a displacement z in a thickness direction of a wafer and is a sum of plural functions. The first function g(r) has a distance r from the center of the wafer as a variable. The second function Ar×h(Nθ) indicates multiplying a sine or cosine function h(Nθ), with a first angle θ with reference to a predetermined position in a circumferential direction of the wafer as a variable and an integer N as a constant, by a coefficient A with the distance r. The third function Br×i(M(θ-φ)) indicates multiplying a sine or cosine function i(M(θ-φ)), with the first angle θ as a variable, a second angle φ with reference to the predetermined position as a constant, and an integer M as a constant, by a coefficient B and the distance r.

### TECHNICAL FIELD

The present invention relates to a method for modeling a wafer profile and a method for manufacturing a wafer.

### BACKGROUND ART

A semiconductor wafer typically requires high flatness. Wafer flatness is commonly determined by measuring a profile of a wafer using a capacitive or optical interferometric profile measuring apparatus and evaluating the measurement with parameters such as Warp and nanotopography.

As a technique for evaluating wafer flatness, Patent Literature 1 discloses a method for accurately evaluating nanotopography through excluding processing strain at a periphery as a disturbance when measuring a wafer profile using a capacitive profile measuring apparatus.

In addition, Patent Literature 2 discloses a method for creating data of a surface profile of the entire wafer by expressing each profile along a radial direction of the wafer by a polynomial with a position r in the radial direction of the wafer as a variable, and repeating the expressing for each predetermined angle θ.

### CITATION LIST

### Patent Literature(S)

Patent Literature 1: Japanese Patent No. 5862492
Patent Literature 2: Japanese Patent No. 6899080

### SUMMARY OF THE INVENTION

### Problem(s) to be Solved by the Invention

However, the method described in Patent Literature 1 does not allow for the evaluation of waviness at the periphery of the wafer, since processing strain at the periphery of the wafer is excluded in order to perform the evaluation by nanotopography.

The method described in Patent Literature 2, which can determine a profile in the radial direction of the wafer, though, cannot determine circumferential waviness.

An object of the invention is to provide a method for modeling a profile of a wafer, the method capable of replicating circumferential waviness over the entire wafer and accurately evaluating the waviness of the wafer, and a method for manufacturing the wafer.

### Means for Solving the Problem(s)

An aspect of the invention provides a method for modeling a wafer profile by using a function, the function being used for calculating a displacement z in a thickness direction of a wafer, the function indicating a sum of a plurality of functions, the plurality of functions including: a first function g(r) that is a first- or higher-order polynomial with a distance r from a center of the wafer as a variable; a second function Ar×h(Nθ) that indicates multiplying a sine or cosine function h(Ne), with a first angle θ with reference to a predetermined position in a circumferential direction of the wafer as a variable and an integer N as a constant, by a coefficient A and the distance r; and a third function Br×i(M(θ-φ)) that indicates multiplying a sine or cosine function i(M(θ-φ)), with the first angle θ as a variable, a second angle φ with reference to the predetermined position as a constant, and an integer M as a constant, by a coefficient B and the distance r.

In the method for modeling a wafer profile according to the above aspect, the second function may be represented by A₁r×h₁(N₁θ)+A₂r×h₂(N₂θ)+ . . . +Aₙr×hₙ(Nₙθ) (n is an integer of 1 or more), and the third function may be represented by B₁r×i₁(M₁(θ−φ))+B₂r×i₂(M₂(θ−φ))+ . . . +Bₘr×iₘ(Mₘ(θ−φ)) (m is an integer of 1 or more).

In the method for modeling a wafer profile according to the above aspect, the predetermined position may be a reference position for indicating a crystal orientation, and the second angle φ may be formed between a cutting feed direction for cutting the wafer from an ingot and a straight line connecting the reference position to a center of the wafer.

In the method for modeling a wafer profile according to the above aspect, the first function may be a third-order polynomial, the second function may be Ar×sin4θ, and the third function may be B₁r×cos2 (θ−φ)+B₂r×cos3 (θ−φ).

According to another aspect of the invention, a method for manufacturing a wafer includes: slicing the wafer by cutting an ingot; grinding and polishing both surfaces of the wafer; modeling a profile of the wafer by using the modeling method according to the above aspect to provide a model; and evaluating the wafer on a basis of the model.

In the method for manufacturing a wafer according to the another aspect of the invention, the evaluating is performed on a basis of a magnitude of each of the coefficients of the function obtained by the modeling method.

### BRIEF DESCRIPTION OF DRAWINGS

FIG. 1 schematically illustrates a positional relationship between a wafer and a wire saw according to an exemplary embodiment of the invention.

FIG. 2 is a map illustrating wafer waviness to be modeled by a first function.

FIG. 3A is a map illustrating wafer waviness to be modeled by a second function.

FIG. 3B is another map illustrating wafer waviness to be modeled by the second function.

FIG. 4 is a graph used in a calculation method of coefficients of the first function.

FIG. 5 is a diagram illustrating measurement points for a displacement z when calculating coefficients of the second and third functions.

FIG. 6 is a graph used in a calculation method of the coefficients of the second and third functions.

FIG. 7 is a flowchart illustrating a manufacturing method of a wafer according to an exemplary embodiment of the invention.

FIG. 8A is a map created in Example 1.

FIG. 8B is another map created in Example 1.

FIG. 9A is a map created in Example 2.

FIG. 9B is another map created in Example 2.

### DESCRIPTION OF EMBODIMENT(S)

An exemplary embodiment of the invention will be described below with reference to the attached drawings.

A method for modeling a wafer profile according to the exemplary embodiment of the invention is a method for replicating, as a model using a function (numerical formula), a profile of each wafer sliced from a monocrystalline ingot manufactured by the Choklarsky method (CZ method) or other methods.

The model is created by the function for calculating a displacement in a thickness direction of the wafer, with a distance from the center of the wafer, an angle with reference to a predetermined position in a circumferential direction of the wafer, and the like as variables.

The method for manufacturing a wafer is characterized by including: modeling the wafer profile for a wafer that has been ground to provide a model; and evaluating the wafer using the model.

Firstly, a method for modeling a wafer profile will be described. A description is made on a wafer having a 300-mm diameter, which is not limited thereto.

The method for modeling a wafer profile according to the exemplary embodiment is a method for modeling a wafer profile by using a function (1) below. The function (1) is used for calculating a displacement z in a thickness direction of the wafer to be modeled. The displacement z in the thickness direction of the wafer can be expressed by the following function (1), where a distance r from the center of the wafer and a first angle θ with reference to a notch position are variables.

$$z = f ( r , θ ) = {ar}^{3} + {br}^{2} + cr + d + Ar \times sin 4 θ + {B}_{1} r \times cos 2 ( θ + φ ) \times cos 3 ( θ - φ ) \qquad ( 1 )$$

That is, the function (1) indicates a sum of plural functions including a first function (ar³+br²+cr+d), a second function (Ar×sin4θ), and a third function (Br×cos2 (θ−φ)+B₂r× cos3 (θ−φ)).

Here, the displacement in the thickness direction of the wafer represents the minimum distance between any point on a thickness median plane of the wafer and a best-fit surface of the thickness median plane. The thickness median plane of the wafer means a plane formed by a set of points located at the center of the thickness at any points on the wafer, where a width in a vertical direction of the wafer placed on a horizontal surface in a natural state is defined as the thickness. The natural state means a state in which no external force is applied to adsorb the wafer to a horizontal surface. The best-fit surface of the thickness median plane means the least-squares plane to the thickness median plane.

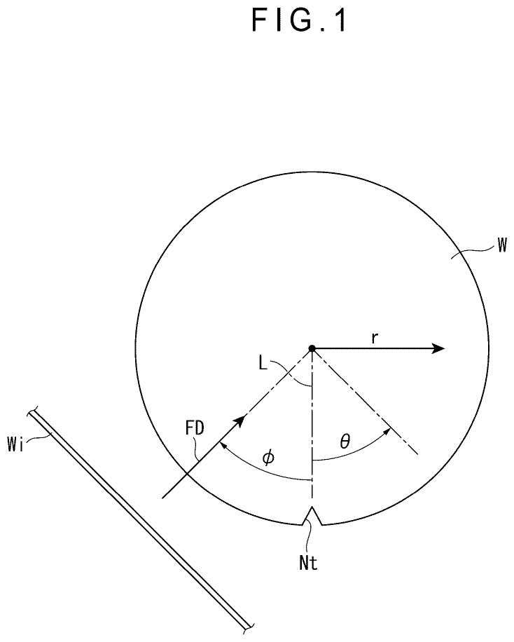

As illustrated in FIG. 1, in the exemplary embodiment, a position where a notch Nt is formed to indicate a crystal orientation (notch position, reference position) is defined as the reference for the angle θ. Here, the angle θ is positive in the counterclockwise direction from the notch position. The reference for the angle θ is not limited to the notch position, but may be a predetermined position commonly defined for wafers that indicates the reference in the circumferential direction, for instance, may be a position where an orientation flat is formed.

The reference for the angle θ is limited to neither the notch Nt position nor the orientation flat position, but may be changed as needed on the basis of a mechanism for forming wafer waviness, or the like.

φ (second angle) is an angle formed between a cutting feed direction FD for slicing wafers from a monocrystalline ingot using a wire saw and a straight line L connecting a notch position to the center of each wafer W. Here, the angle q is positive in the counterclockwise direction from the notch position. The cutting feed direction FD by the wire saw is a direction orthogonal to an extending direction of a wire Wi of the wire saw.

In the function (1), “ar³+br²+cr+d” (referred to as the first function) is a polynomial that approximates warpage of the wafer. The first function is a one-variable third-order polynomial in which the distance r from the center of the wafer is a variable. a, b, c, and d are coefficients calculated by a calculation method described below, and are parameters that determine warpage of a model obtained mainly by the function (1).

The first function, which is the third-order polynomial in the exemplary embodiment, is not limited thereto, but may be changed on a basis of accuracy required for a model, or the like. For instance, the first function can be a first-order polynomial if wafer warpage is presumed simple, or a fourth- or higher-order polynomial if wafer warpage is presumed complex.

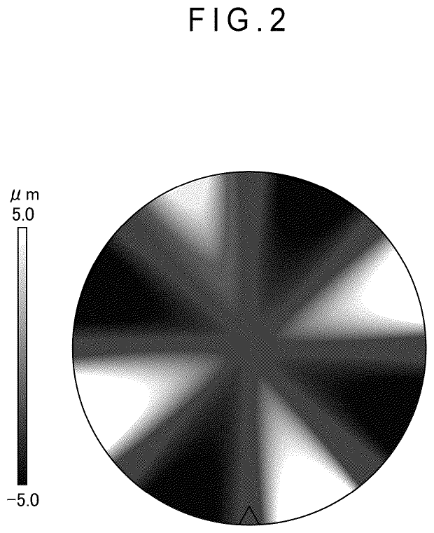

In the function (1), “Ar×sin4θ” (referred to as the second function) is a sine function that approximates the profile of the wafer W waving four times in the circumferential direction (sinusoidal profile oscillating four times in one circumference, or cross-profiled waviness appearing on the wafer), as illustrated in FIG. 2. “A” in the second function is a coefficient calculated by the calculation method described below, and is a parameter that determines a size of circumferential waviness of a model obtained mainly by the function.

The inventors found that grinding wafers generated waviness as illustrated in FIG. 2, and incorporated the second function into the function (1) in order to reflect this waviness in the model. Examples of a grinding method that causes such waviness include resin-applied grinding (see, for instance, JP 2011-249652 A) and single-sided abrasive grinding.

The second function is “Ar×sin4θ” in the exemplary embodiment. However, waviness may be approximated by using a cosine function (cos), without limiting to a sine function (sin), as the trigonometric functions because the cosine function (cos) is the same as the sine function (sin) in terms of periodic changes. In the exemplary embodiment, the number of waviness is four. However, the number of waviness may be changed depending on the profile of the waviness generated.

In other words, it is sufficient that the second function is the function Ar×h(Nθ), which indicates multiplying a sine or cosine function h(Nθ), with the first angle θ as a variable and the integer N as a constant, by the coefficient A and the distance r.

The number of trigonometric functions may be increased in order to model the wafer profile on the basis of further findings. Specifically, the second function may be represented by

$${A}_{1} r \times {h}_{1} ( {N}_{1} θ ) + {A}_{2} r \times {h}_{2} ( {N}_{2} θ ) + … + {A}_{n} r \times {h}_{n} ( {N}_{n} θ )$$

$$( n is an integer of 1 or more ) .$$

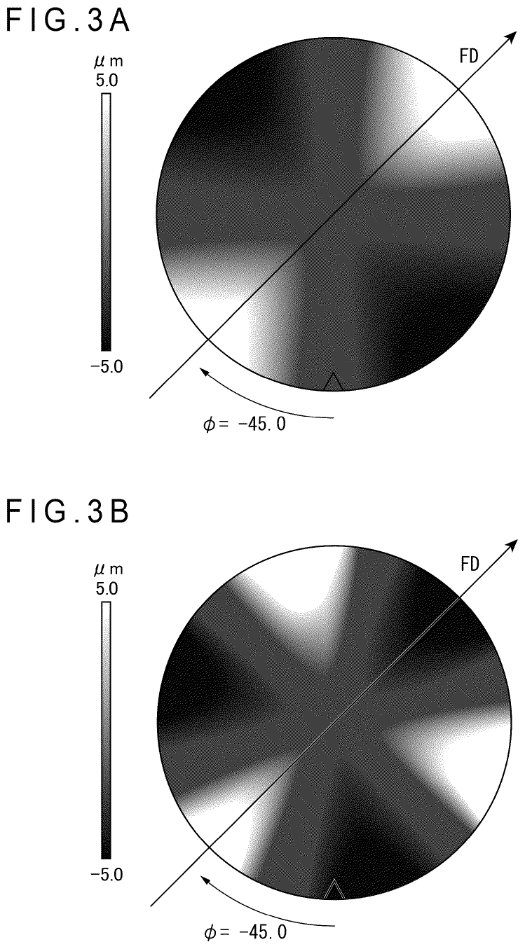

In the function (1), “B₁r×cos2 (θ−φ)+B₂r×cos3 (θ−φ)” (referred to as the third function) is a cosine function that approximates the profile of the wafer waving twice in the circumferential direction (sinusoidal profile oscillating twice in one circumference) and the profile of the wafer waving three times (sinusoidal profile oscillating three times in one circumference), as illustrated in FIGS. 3A and 3B.

“B₁ and B₂” in the third function are coefficients calculated by the calculation method described below, and, similar to the “A” in the second function, are parameters that determine a size of waviness of a wafer model obtained mainly by the function.

The inventors found that waviness as described above was generated depending on the cutting feed direction FD of the wire saw when a monocrystalline ingot was sliced using the wire saw to obtain wafers, and incorporated the third function into the function (1) in order to reflect this waviness in the wafer model.

The third function is “B₁r×cos2 (θ−φ)+B₂r×cos3 (θ−φ)” in the exemplary embodiment. However, waviness may be approximated using a sine function (sin), without limiting to a cosine function, as the trigonometric functions. In the exemplary embodiment, the number of waviness is two or three. However, the number of waviness may be changed depending on the profile of the waviness generated. The number of trigonometric functions in the third function may be one.

In other words, it is sufficient that the third function is the function Br×i(M(θ−φ)), which indicates multiplying a sine or cosine function i(M(θ−φ)), with the first angle θ as a variable and the second angle q and an integer M each as a constant, by a coefficient B and the distance r.

Similar to the second function, the number of trigonometric functions may be increased in order to model the wafer profile on the basis of further findings. Specifically, the third function may be represented by

$${B}_{1} r \times {i}_{1} ( {M}_{1} ( θ - φ ) ) + {B}_{2} r \times {i}_{2} ( {M}_{2} ( θ - φ ) ) + … + {B}_{m} r \times {i}_{m} ( {M}_{m} ( θ - φ ) )$$

$$( m is an integer of 1 or more ) .$$

### Calculation Method of Coefficients of First Function (Third-order Polynomial)

Next, a calculation method of coefficients (a, b, c, d) in a polynomial will be described.

(1) Displacements Zr are measured at plural points at every distance r from the center of a wafer and are averaged in a circumferential direction.

With respect to the wafer to be a modeling target, the displacements zᵣ are measured at plural points at every distance r from the center of the wafer. The displacements zᵣ of the wafer, which are values of displacements measured by a measuring apparatus, can be measured by, for instance, a capacitive profile measuring apparatus. The plural points on the circumference are preferably set at an equal distance and may be measured at, for instance, 360 points every one degree. An average value of the displacements zᵣ measured at the plural points is defined as a displacement z_{avg} at the distance r from the center. Then, the displacement z_{avg} is calculated for each distance r from the center. The distance r to be set is preferably as short as possible. In the exemplary embodiment, the distance r is set from r=0 (center of the wafer) to r=146 (near a periphery of the wafer) in 1 mm increments.

(2) An approximate expression for the displacements z_{avg} with respect to the distances r from the center is obtained.

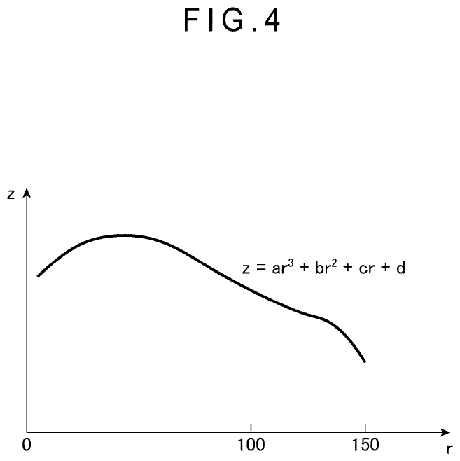

The distances r and the displacements z_{avg} are plotted on a graph as illustrated in FIG. 4 to obtain an approximate expression of a third-order polynomial. The approximate expression may be obtained using the least-square method. The coefficients (a, b, c, d) of the obtained approximate expression are the coefficients of the first function.

As described above, the approximate expression is not limited to the third-order polynomial.

### Calculation Method of Coefficients of Second and Third Functions

Next, a calculation method of coefficients (A, B₁, B₂) of the second and third functions will be described.

(1) The distance r from the center of the wafer is determined at any value.

The distance r from the center of the wafer is determined at any value indicating a position for measuring the displacements zᵣ in a thickness direction of the wafer. In the exemplary embodiment, the distance r is set at 146 mm. The distance r from the center of the wafer may be at any value. However, since the wafer has a larger waviness at the periphery, the distance r is also preferably a large value.

(2) The displacements zᵣ in the thickness direction of the wafer are measured.

At the distance r, the displacements zᵣ in the thickness direction of the wafer are measured (actually measured) every any angle in the circumferential direction.

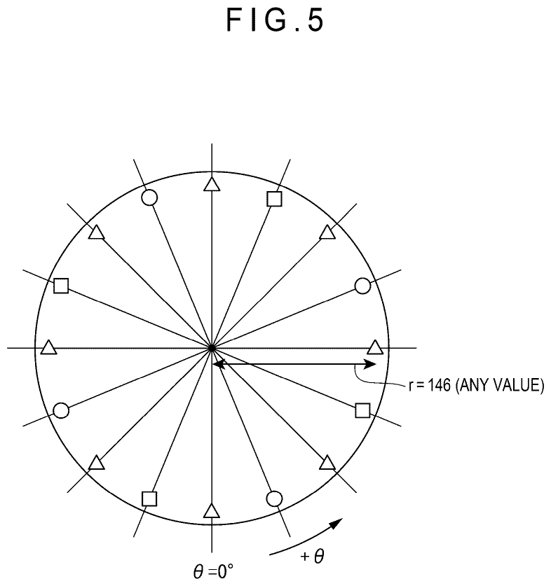

The any angle may be, for instance, 22.5 degrees as illustrated in FIG. 5. In this case, the number of measurement points is 16 at an equal distance in the circumferential direction. The displacements zᵣ are measured counterclockwise, starting from the position 0=0 degrees.

(3) An approximate expression of the displacements zᵣ with respect to values obtained by multiplying the distance r by a trigonometric function is obtained.

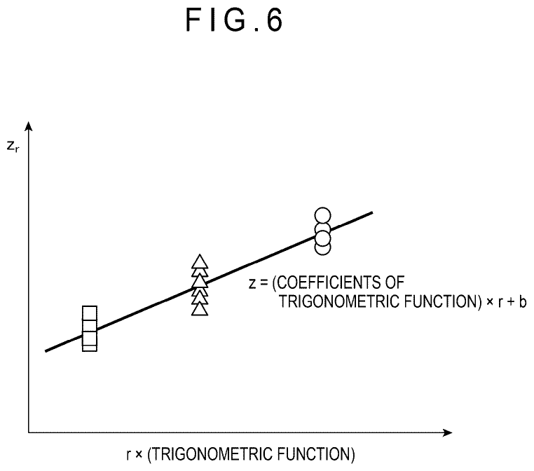

The values obtained by multiplying the distance r by a trigonometric function (sin4θ, cos2 (θ−φ), or cos3 (θ−φ)) and the displacements zᵣ are plotted on a graph as illustrated in FIG. 6 to obtain a first-order approximate expression.

As described above, φ is an angle determined depending on the cutting feed direction FD and, for instance, can be −45 degrees.

For instance, for determining the coefficient A of the second function (Ar×sin4θ), the horizontal axis indicates r×sin40 and the vertical axis indicates the displacement zr. For instance, for determining the coefficient A of the second function (Ar×sin4θ) and measuring the displacement zᵣ in the wafer thickness direction every 22.5 degrees, obtained are three different values of r×sin40 (horizontal axis values) (0 (marked with Δ(triangle) in FIG. 5), r (marked with ∘ (circle) in Fig.e 5) and −r (marked with (square) in FIG. 5). Depending on the trigonometric function to be determined and any angle described above, how many different values of r×the trigonometric function are obtained and how many points of the displacement are plotted at each value on the horizontal axis will change.

It should be noted that an approximate expression may be obtained using the least-square method. The coefficients of the obtained approximate expression are the coefficients (A, B₁, B₂) of the second and third functions.

Through the above steps, the coefficients a, b, c, d, A, B₁, and B₂ are calculated to obtain the function (1). An operator can draw a model of the wafer by entering the function (1) into a computer or the like to determine a profile (warpage, waviness) of the wafer.

The profile of the wafer can also be determined by the coefficients obtained, without drawing a model. For instance, the operator can judge that the waviness at the periphery of the wafer is larger as the coefficients A, B₁, and B₂ are larger.

### Method for Manufacturing Wafer

Next, a method for manufacturing a wafer using the above wafer profile modeling method will be described.

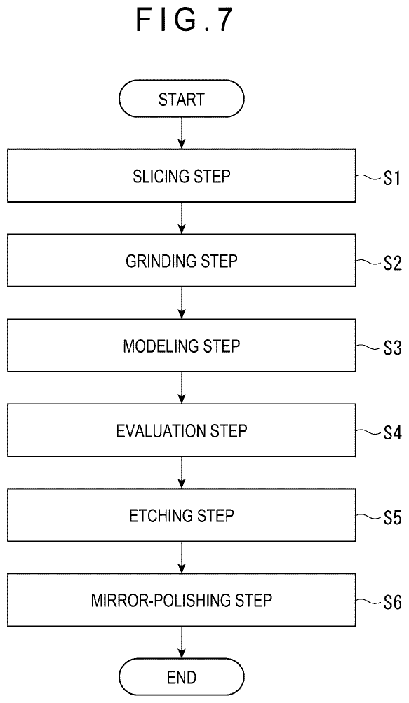

As illustrated in FIG. 7, the method for manufacturing a wafer includes a slicing step S1, a grinding step S2, a modeling step S3, an evaluation step S4, an etching step S5, and a mirror-polishing step S6.

In the slicing step S1, a monocrystalline ingot (or a block obtained by cutting a monocrystalline ingot) is cut using a cutter such as a wire saw to cut out a plurality of wafers. A plurality of wafers each having a thickness, for instance, about 1 mm are thus obtained. A cutting feed direction FD by a wire saw can be determined, for instance, with reference to a notch position.

It should be noted that a lapping step may be conducted between the slicing step S1 and the grinding step S2. A step of chamfering an outer edge of the wafer, which is not particularly described, may be conducted including primary chamfering after the slicing step S1 and secondary chamfering after the grinding step S2, the secondary chamfering being larger than the primary chamfering in chamfering amount.

In the grinding step S2, both sides of the wafer are ground using a grinding apparatus. Examples of a grinding method include resin-applied grinding, single-sided abrasive grinding and simultaneous double-sided grinding.

In the modeling step S3, the wafer having undergone the grinding step S2 is subjected to modeling by using a wafer profile modeling method. Specifically, the coefficients a, b, c, d, A, B₁ and B₂ of the function (1) are obtained by measuring the displacement zᵣ in a thickness direction of the wafer at each distance r using a capacitive profile-measuring apparatus or the like. The obtained function (1) is used to draw a model of the wafer using a computer or the like.

In the evaluation step S4, the operator evaluates the wafer with reference to the wafer model obtained in the modeling step S3. The operator can understand warpage and waviness of the wafer by referring to the model On the basis of the warpage and waviness of the wafer, the operator can again grind the wafer as needed and judge whether the wafer is satisfactory or unsatisfactory.

The etching step S5 is a step for performing chemical etching in order to remove machining damage caused on a surface of the wafer in the previous steps.

The mirror-polishing step S6 is a step for polishing both sides of the wafer using a polishing apparatus.

In the etching step S5 and the mirror-polishing step S6, the etching method and the polishing method can be tuned on the basis of the results of the evaluation step S4.

According to the above method for modeling the wafer profile, since the trigonometric functions are included in the function (1) and, owing to this trigonometric functions, the circumferential waviness of the entire wafer can be replicated, the waviness of the wafer can be evaluated accurately.

Especially, circumferential waviness that is presumed to be caused by the wire saw and the waviness that is presumed to be caused by the grinding step can be independently replicated.

The modeling accuracy can also be increased by increasing the order of the first function and the number of trigonometric functions.

According to the above wafer manufacturing method, it is possible to evaluate the wafer based on the warpage and waviness of the wafer before performing the etching step S5 and the mirror-polishing step S6.

### Example 1

Next, the invention will be more specifically described with reference to Examples. In Example 1, there were created a map of a wafer using only measurement values and a map using a model obtained by the wafer profile modeling method of the invention, and the two maps are compared.

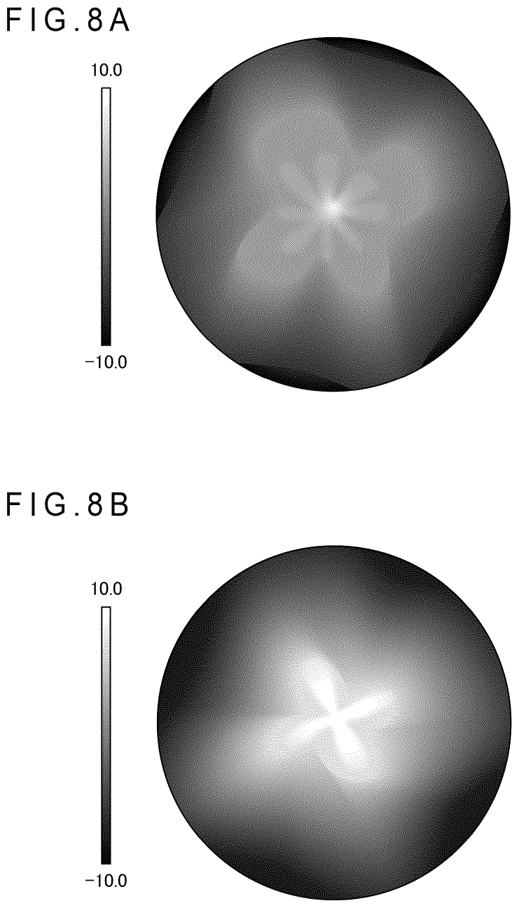

First, a profile of a wafer was measured using a capacitive profile measuring apparatus and a map illustrated in FIG. 8A was created based on the measurement values.

Moreover, a function was obtained by the wafer profile modeling method of the invention, and a map as illustrated in FIG. 8B was creased using a model obtained through this function. Table 1 shows coefficients of the function.

TABLE 1

| a (μm/mm³) | b (μm/mm²) | c (μm/mm) | d (μm) | A (μm/mm) | B₁ (μm/mm) | B₂ (μm/mm) | ϕ (deg) |
|---|---|---|---|---|---|---|---|
| −1.02 × 10⁻⁷ | −5.27 × 10⁻⁴ | −1.35 × 10⁻² | 7.01 | 1.55 × 10⁻² | 5.91 × 10⁻³ | 5.99 × 10⁻³ | −44.3 |

As understood from a comparison between FIGS. 8A and 8B, the map created using only the measurement values and the map created using the model conform with each other, particularly in waviness at their peripheries.

### Example 2

Next, Example 2 of the invention will be described. In Example 2, two wafers having undergone the grinding step were modeled using the wafer profile modeling method.

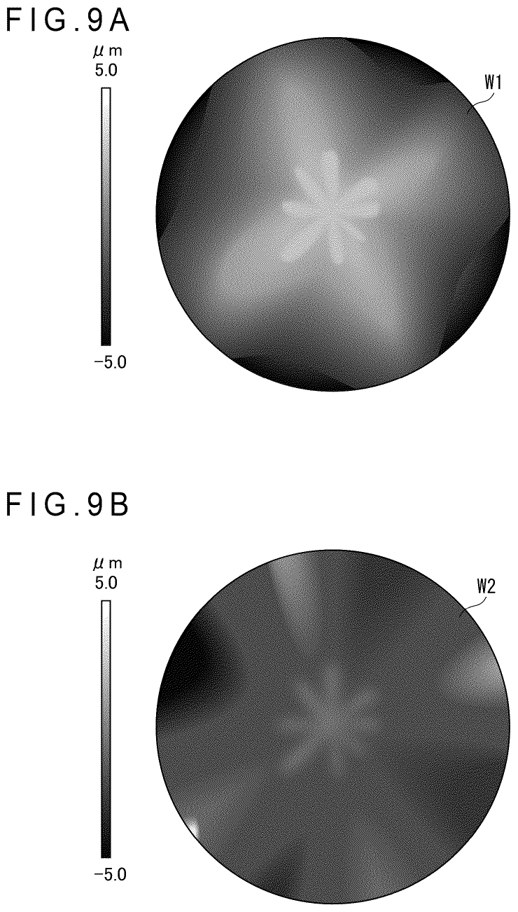

FIGS. 9A and 9B are maps created based on actual measurement values of the two prepared wafers W1 and W2. It is seen from the maps that profiles of the respective wafers are significantly different from each other. Both of the wafers used are after being subjected to the grinding step (resin-applied grinding) . . .

Table 2 shows coefficients for each of the two wafers, the coefficients calculated using the wafer profile modeling method.

TABLE 2

| | a (μm/mm³) | b (μm/mm²) | c (μm/mm) | d (μm) | A (μm/mm) | B₁ (μm/mm) | B₂ (μm/mm) | ϕ (deg) |
|---|---|---|---|---|---|---|---|---|
| Wafer 1 | −9.71 × 10⁻⁷ | −1.60 × 10⁻⁵ | −3.15 × 10⁻² | 4.42 | 1.67 × 10⁻² | 3.76 × 10⁻³ | 4.84 × 10⁻³ | −45 |
| Wafer 2 | 7.03 × 10⁻⁷ | 2.04 × 10⁻⁵ | −1.91 × 10⁻² | 1.54 | 1.68 × 10⁻² | 6.84 × 10⁻³ | 4.36 × 10⁻³ | −45 |

The coefficient A of the wafer W1 is approximately the same as the coefficient A of the wafer W2, indicating that the degrees of the waviness, which is presumably caused by the grinding step, are similar. Moreover, since the coefficients a, b, c, and d of the polynomial are significantly different between the wafer W1 and the wafer W2, it is understood that a significant difference between the two maps are affected by the warpage of the wafers.

### EXPLANATION OF CODES

L . . . straight line connecting a notch position and a center of a wafer,
Nt . . . notch, r . . . distance from a center of a wafer, W . . . wafer, z . . .
displacement in a thickness direction of a wafer, θ . . . first angle with
reference to a notch position, φ . . . second angle defined by a cutting feed
direction, S1 . . . slicing step, S2 . . . grinding step, S3 . . . modeling step,
S4 . . . evaluation step, S5 . . . etching step, S6 . . . mirror-polishing step

I claim:

1. A method for modeling a wafer profile by using a function, the function being used for calculating a displacement z in a thickness direction of a wafer,
the function indicating a sum of a plurality of functions, the plurality of functions including:
a first function g(r) that is a first- or higher-order polynomial with a distance r from a center of the wafer as a variable;
a second function Ar×h(Nθ) that indicates multiplying a sine or cosine function h(Nθ), with a first angle θ with reference to a predetermined position in a circumferential direction of the wafer as a variable and an integer N as a constant, by a coefficient A and the distance r; and
a third function Br×i(M(θ−φ)) that indicates multiplying a sine or cosine function i(M(θ)−φ)), with the first angle θ as a variable, a second angle q with reference to the predetermined position as a constant, and an integer M as a constant, by a coefficient B and the distance r.

2. The method for modeling a wafer profile according to claim 1, wherein
the second function is represented by A₁r×h₁(N₁θ)+A₂r×h₂ (N₂θ)+ . . . +Aₙr×hₙ(Nₙθ) (n is an integer of 1 or more), and
the third function is represented by B₁r×i₁(M₁(θ−φ)+B₂r×i₂(M₂(θ−φ)+ . . . +Bₘr×iₘ(Mₘ(θ−φ)) (m is an integer of 1 or more).

3. The method for modeling a wafer profile according to claim 1, wherein
the predetermined position is a reference position for indicating a crystal orientation, and
the second angle φ is formed between a cutting feed direction for cutting the wafer from an ingot and a straight line connecting the reference position to a center of the wafer.

4. The method for modeling a wafer profile according to claim 3, wherein
the first function is ar³+br²+cr+d,
the second function is Ar×sin4θ, and
the third function is B₁r×cos2 (θ−9)+B₂r×cos3 (θ−φ).

5. A method for manufacturing a wafer, comprising:
slicing the wafer by cutting an ingot;
grinding and polishing both surfaces of the wafer;
modeling a profile of the wafer by using the modeling method according to claim 1 to provide a model; and
evaluating the wafer on a basis of the model.

6. The method for manufacturing a wafer according to claim 5, wherein
the evaluating is performed on a basis of a magnitude of each of the coefficients of the function obtained by the modeling method.
